(19) United States
(12) Patent Application Publication
(10) Pub. No.: US 2014/0294207 A1
(43) Pub. Date: Oct. 2, 2014

(54) AMPLIFIER OUTPUT COVER AND CONNECTOR

(71) Applicant: Harman International Industries, Inc., Stamford, CT (US)

(72) Inventor: Robert Siegel, Niles, MI (US)

(73) Assignee: Harman International Industries, Inc., Stamford, CT (US)

(21) Appl. No.: 14/227,738

(22) Filed: Mar. 27, 2014

Related U.S. Application Data
(60) Provisional application No. 61/805,684, filed on Mar. 27, 2013.

(51) Int. Cl. H03F 1/00

(52) U.S. Cl. CPC H03F 1/00
USPC 381/120

(57) ABSTRACT

In at least one embodiment, an audio amplifier apparatus including a connector is provided. The apparatus includes a connector having a plurality of first openings. Each first opening being arranged to receive a first fastening mechanism to couple the connector to a first side of an audio amplifier. The connector further includes a plurality of second openings to enable access to a plurality of second fastening mechanisms which provide an electrical output from the audio amplifier. The connector further includes a plurality of terminal channels being angularly offset from the plurality of second openings. Each terminal channel being configured to receive a connection terminal to connect to a corresponding second fastening mechanism to electrically couple the connection terminal to the audio amplifier.

### CROSS-REFERENCE TO RELATED APPLICATIONS

This application claims the benefit of U.S. provisional Application No. 61/805,684 filed Mar. 27, 2013, the disclosure of which is incorporated in its entirety by reference herein.

### TECHNICAL FIELD

Embodiments disclosed herein generally relate to an amplifier output cover and connector.

### BACKGROUND

Audio amplifiers used in connection with amplifying audio signals for large venues such as fixed installs are known to provide a large amount of power for powering various speakers. In general, the amplifier may have a connector block positioned on a back side thereof for enabling wire and terminals to be coupled thereto. The wire may extend out from the amplifier and electrically couple the speaker to the amplifier. The terminal, while connected to the connector block, may be exposed. In addition, a receiving mechanism on the connector block is used to couple the terminal to the connector block. The receiving mechanism may also be exposed. Due to the large amount of current that is provided from the amplifier to the speaker, a cover is generally provided to prevent human contact with the terminals and/or the receiving mechanisms.

### SUMMARY

In at least one embodiment, an audio amplifier apparatus including a connector is provided. The apparatus includes a connector having a plurality of first openings. Each first opening being arranged to receive a first fastening mechanism to couple the connector to a first side of an audio amplifier. The connector further includes a plurality of second openings to enable access to a plurality of second fastening mechanisms which provide an electrical output from the audio amplifier. The connector further includes a plurality of terminal channels being angularly offset from the plurality of second openings. Each terminal channel being configured to receive a connection terminal to connect to a corresponding second fastening mechanism to electrically couple the connection terminal to the audio amplifier.

In at least another embodiment, an audio amplifier apparatus including a connector is provided. The connector includes a plurality of first openings. Each first opening is arranged to receive a first fastening mechanism to couple the connector to a first side of an audio amplifier. The connector further includes a plurality of second openings to enable access to a plurality of second fastening mechanisms which provide an electrical output from the audio amplifier. The connector further includes a plurality of terminal channels being angularly offset from the plurality of first openings and the plurality of second openings. Each terminal channel being configured to receive a connection terminal to connect to a corresponding second fastening mechanism to electrically couple the connection terminal to the audio amplifier.

In at least another embodiment, an audio amplifier apparatus including a connector is provided. The connector includes a plurality of first openings, each first opening being arranged to receive a first fastening mechanism to couple the connector to a first side of an audio amplifier. The connector further includes a plurality of second openings orientated away from the first side of the audio amplifier. The plurality of second openings to enabling access to a plurality of second fastening mechanisms which provide an electrical output from the audio amplifier. The connector further includes a plurality of terminal channels positioned on a top side of the connector. Each terminal channel is configured to receive a connection terminal to connect to a corresponding second fastening mechanism to electrically couple the connection terminal to the audio amplifier.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompany drawings in which:

FIG. 1 depicts an amplifier including a connector block for electrically coupling an amplifier to a plurality of speakers;

FIG. 2 depicts a safety cover coupled to the amplifier;

FIG. 3 depicts an amplifier connector/cover in accordance to one embodiment;

FIG. 4 depicts the amplifier connector/cover as attached to an amplifier; and

FIG. 5 depicts a view of a wire and fork terminal.

### DETAILED DESCRIPTION

As required, detailed embodiments are disclosed herein; however, it is to be understood that the disclosed embodiments are merely examples of the present disclosure that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present disclosure.

Embodiments disclosed herein generally provide for a connector/cover used in connection with a high power output amplifier for powering one or more speakers. The connector/cover receives one or more electrical terminals for electrically coupling the amplifier to the speaker and further prevents a user from contacting the one or more electrical terminals. The connector/cover is generally a single piece design that prevents the need for multiple installation operations. These aspects and others will be discussed in more detail below.

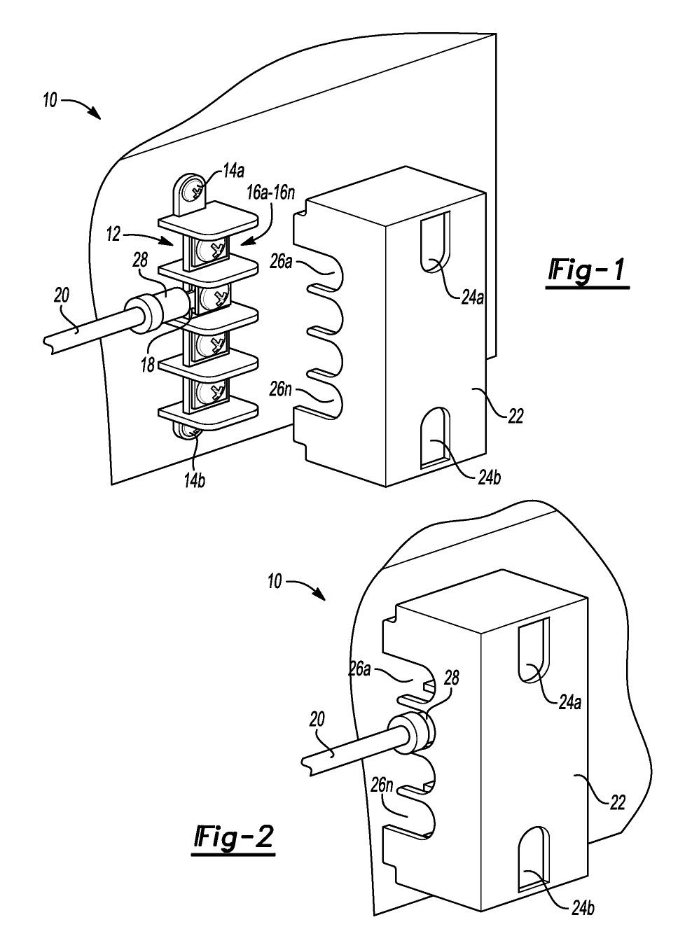

FIG. 1 depicts an amplifier 10 including a connector block 12 for electrically coupling the amplifier 10 to a plurality of speakers (not shown). A first set of screws 14a-14b is used to couple the connector block 12 to a rear panel of the amplifier 10. A second set of screws 16a-16n (“16”) is provided for electrically coupling a plurality of fork terminals 18. A wire 20 is coupled to the terminal 18 for providing an output current from the amplifier 10 to the speaker.

The amplifier 10 may transmit a large amount of power from a respective output of the connector block 12 (via one or more of the screws 16) to the fork terminal 18 and subsequently to the speaker by way of the wire 20. In this case, the wire 20 may be a 10 gauge wire to support the current needed to be provided from the amplifier 10 to the speaker. As illustrated, the second set of screws 16 and the fork terminal 18 may be exposed and therefore may come into contact with a user. A safety cover 22 is coupled to amplifier 10 and is arranged to cover the second set of screws 16 and the fork terminal 18 (see FIG. 2 for additional reference to safety cover 22). The use of the safety cover 22 prevents the user from coming into contact with the second screws 16 and the fork terminal 18, and compliance with Universal Safety (“UL”) standards.

In order to attach the safety cover 22 to the amplifier 10, the user is required to remove the first set of screws 14a-14b. The safety cover 22 includes a first set of receiving channels 24a-24b for receiving the first set of screws 14a-14b, respectively, such that the safety cover 22 is coupled to the amplifier 10. The safety cover 22 includes a plurality of overlapping channels 26a-26n (“26”), each overlapping channel 26 is arranged to be placed over a respective end 28a-28n (“28”) of the wire 20 when the safety cover 22 is coupled to the amplifier 10. The placement of the overlapping channel 26 over the corresponding end 28 also prevents the user from contacting any portion of the fork terminal 18 and/or the second set of screws 16. While the safety cover 22 may be adequate for preventing the user from contacting the fork terminal 18 and/or any one of the second set of screws 16, the user is required to remove the safety cover 22 from the amplifier 10 prior to coupling the fork terminal 18 to any one of the second set of screws 16.

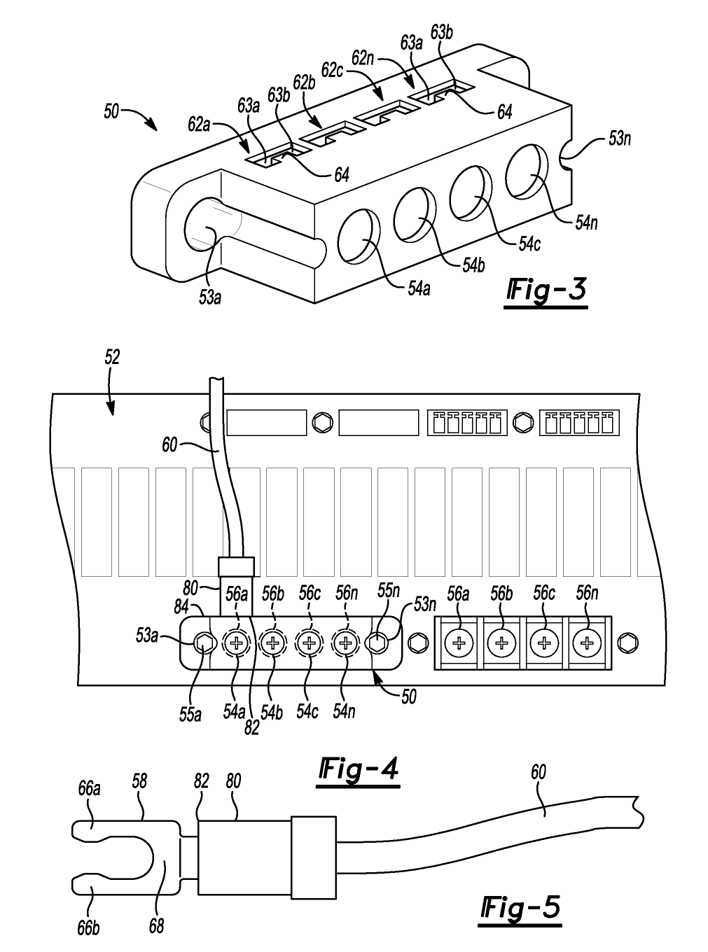

FIG. 3 depicts an amplifier connector/cover 50 (or audio amplifier apparatus) in accordance to one embodiment. The amplifier connector/cover 50 may be used in connection with an audio amplifier 52 (see FIG. 4 for the amplifier 52) that amplifies audio signals for large venues or that provide a large amount of power for powering various speakers (not shown). With reference to FIGS. 3-5, the connector/cover 50 defines a plurality of first openings 53a-53n (“53”) for receiving a first set of fastening mechanisms (or first plurality of fastening mechanisms) 55a-55n (“55”). The first set of fastening mechanisms 55 couple the connector/cover 50 to the amplifier 52. For example, as shown in FIG. 4, the first set of fastening mechanisms 55 couple to connector/cover 50 to a rear side of the amplifier 52.

The connector/cover 50 further defines a plurality of second openings 54a-54n for enabling access to a second set of fastening mechanisms 56a-56n (see FIG. 4). As shown in FIG. 5, the plurality of second openings 55a-55n is oriented to face away from the rear side of the amplifier 52. The second set of fastening mechanisms 56a-56n are provided for mechanically and electrically coupling any one or more fork terminals 58 (or connection terminals) to the amplifier 52 (see FIGS. 4-5). A wire 60 is coupled to the terminal 58 for providing an output current from the amplifier 52 to the speaker. It is recognized that the fastening mechanisms 56 may comprise screws, fasteners or other suitable devices that can couple the terminals 58 to the amplifier 52 and further enable the transfer of current from the amplifier 52 through the wire 60 and subsequently to the speaker. For example, the fastening mechanisms 56 may be arranged from materials that are electrically conductive.

The connector/cover 50 further defines a plurality of terminal channels 62a-62n (“62”) (see FIG. 3) for receiving a respective fork terminal 58. Each terminal channel 62 includes a pair of extender receivers 63a-63b, and a tab 64. As shown in FIG. 3, the tab 64 extends within the channel 62 to define a first extender receiver 63a or 63b on each side thereof As also shown in FIG. 3, each terminal channel 62 may be generally C-shaped, in which the tab 64 is provided thereon. Each fork terminal 58 includes a pair of extenders portions 66a and 66b and a generally flat portion 68 (see FIG. 5).

To fasten the fork terminal 58 to the connector/cover 50, a user first inserts the extenders portions 66a and 66b of the fork terminal 58 into the extender receiver 63a and 63b of the terminal channel 62, respectively, until the generally flat portion 68 abuts or contacts the tab 64 of the connector/cover 50. At that point, a corresponding fastening mechanism 56 within a corresponding second opening 54 is fastened to secure the fork terminal 58 to an output terminal (not shown) that is positioned on the amplifier 52. One or more of the extender receivers 63a and 63b may receive bare wire if the fork terminal 58 is not used. The user may insert the bare wire into a particular extended receiver 63a. The user may then secure the fastening mechanism 56 to the bare wire and to an output terminal of the amplifier 52.

Generally, the second opening 54a is arranged to have a diameter that enables a screw driver or other tool to be inserted into the second opening 54 to allow a user to tighten the fastening mechanism 56 for coupling the fork terminal 58 to the amplifier 52. The diameter of the second opening 54 is generally arranged or sized to prevent the fastening mechanism 56 from being removed from the connector/cover 50. While not shown in FIG. 4, the terminal channels 62a-62n are positioned on a top side of the connector/cover 50.

As generally shown in FIGS. 3, the orientation of the terminal channels 62a-62n is angularly offset from the plurality of first openings 53a-53n and the plurality of second openings 554a-54n. In particular, the orientation of the terminal channels 62a-62n is generally perpendicular with respect to the orientation of the plurality of second openings 54a-54n. This condition provides the user with the ability to insert and hold the fork terminal 58 in a corresponding terminal channel 62 while at the same time securing or fastening the fastening mechanism 56 within a second opening 54 to the fork terminal 58 in a single operation (see FIG. 4). As is also generally shown, the user is capable of fully inserting the fork terminal 58 into the terminal channel 62 such that the fork terminal 58 and/or the fastening mechanism 56 is not capable of direct human contact when the fastening mechanism 56 is secured to the fork terminal 58. This condition enables the connector/cover 50 to meet the UL requirement of preventing contact with the high current output from the amplifier 52.

Referring back to FIGS. 4, an end cover 80 is placed over an end portion of the wire 60 and over a portion of the fork terminal 58. As shown in FIG. 4, the end cover 80 generally prevents the user from contacting the fork terminal 58. Further, as also shown in FIG. 4, the end cover 80 includes an outer abutting end 82 for contacting an outer contacting area 84 of the connector/cover 50. As shown in FIG. 4, the user may insert the fork terminal 58 into the connector/cover 50 until the outer abutting end 82 of the fork terminal 58 contacts the outer contacting area 84. This condition ensures that the extender portions 68a-68b of the fork terminal 58 is properly positioned to a desired area over a corresponding fastening mechanism 56. The user may then secure the fastening mechanism 56 to the extender portions 68a-68b of the fork terminal 58 to secure the fork terminal 58 to the amplifier 52.

It is further recognized that the user is not required to employ multiple steps in order to couple the fork terminal 18 to the connector/cover 50 and the connector/cover 50 to the amplifier 52 as noted with the implementation as set forth in connection with FIGS. 1-2.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. An audio amplifier apparatus comprising:
a connector including:
a plurality of first openings, each first opening being arranged to receive a first fastening mechanism to couple the connector to a first side of an audio amplifier;
a plurality of second openings to enable access to a plurality of second fastening mechanisms which provide an electrical output from the audio amplifier; and
a plurality of terminal channels being angularly offset from the plurality of second openings, each terminal channel being configured to receive a connection terminal to connect to a corresponding second fastening mechanism to electrically couple the connection terminal to the audio amplifier.

2. The apparatus of claim 1 wherein the plurality of terminal channels is angularly offset from the plurality of first openings.

3. The apparatus of claim 2 wherein the plurality of terminal channels is angularly offset from the plurality of first opening and the plurality of second openings at an angle that is generally ninety degrees.

4. The apparatus of claim 1 wherein the plurality of second openings are orientated to face away from the first side of the audio amplifier.

5. The apparatus of claim 1 wherein each terminal channel includes a tab extending through the terminal channel to define a first extender receiver on one side of the tab and a second extender receiver on another side of the tab.

6. The apparatus of claim 5 wherein the connection terminal is a fork terminal including a first extender portion and a second extender portion, the first extender receiver to receive the first extender portion and the second extender receiver to receive the second extender portion to couple the fork terminal to the second fastening mechanism.

7. The apparatus of claim 1 wherein the plurality of terminal channels is orientated on a top surface of the connector for receiving the connection terminal and the plurality of second openings is orientated on the connector to face away from the first side of the amplifier for enabling a user to secure the second fastening mechanism to the connection terminal when the connection terminal is received at the terminal channel.

8. An audio amplifier apparatus comprising:
a connector including:
a plurality of first openings, each first opening being arranged to receive a first fastening mechanism to couple the connector to a first side of an audio amplifier;
a plurality of second openings to enable access to a plurality of second fastening mechanisms which provide an electrical output from the audio amplifier; and
a plurality of terminal channels being angularly offset from the plurality of first openings and the plurality of second openings, each terminal channel being configured to receive a connection terminal to connect to a corresponding second fastening mechanism to electrically couple the connection terminal to the audio amplifier.

9. The apparatus of claim 8 wherein the plurality of terminal channels is angularly offset from the plurality of first openings at an angle that is generally ninety degrees.

10. The apparatus of claim 8 wherein the plurality of terminal channels is angularly offset from the plurality of second opening at an angle that is generally ninety degrees.

11. The apparatus of claim 8 wherein the plurality of second openings are orientated to face away from the first side of the audio amplifier.

12. The apparatus of claim 8 wherein each terminal channel includes a tab extending through the terminal channel to define a first extender receiver on one side of the tab and a second extender receiver on another side of the tab.

13. The apparatus of claim 12 wherein the connection terminal is a fork terminal that includes a first extender portion and a second extender portion, the first extender receiver to receive the first extender portion and the second extender receiver to receive the second extender portion to couple the fork terminal to the second fastening mechanism.

14. The apparatus of claim 8 wherein the plurality of terminal channels is orientated on a top surface of the connector for receiving the connection terminal and the plurality of second openings is orientated on the connector to face away from the first side of the amplifier for enabling a user to secure the second fastening mechanism to the connection terminal when the connection terminal is received at the terminal channel.

15. An audio amplifier apparatus comprising:
a connector including:
a plurality of first openings, each first opening being arranged to receive a first fastening mechanism to couple the connector to a first side of an audio amplifier;
a plurality of second openings orientated away from the first side of the audio amplifier, the plurality of second openings to enable access to a plurality of second fastening mechanisms which provide an electrical output from the audio amplifier; and
a plurality of terminal channels positioned on a top side of the connector, each terminal channel being configured to receive a connection terminal to connect to a corresponding second fastening mechanism to electrically couple the connection terminal to the audio amplifier.

16. The audio amplifier apparatus of claim 15 wherein the plurality of terminal channels are angularly offset from the plurality of second openings.

17. The audio amplifier apparatus of claim 16 wherein the plurality of terminal channels is angularly offset from the plurality of first openings at an angle that is generally ninety degrees.

18. The apparatus of claim 15 wherein the plurality of terminal channels is angularly offset from the plurality of first openings at an angle that is generally ninety degrees.

19. The apparatus of claim 15 wherein each terminal channel includes a tab extending through the terminal channel to define a first extender receiver on one side of the tab and a second extender receiver on another side of the tab.

20. The apparatus of claim 19 wherein the connection terminal is a fork terminal including a first extender portion and a second extender portion, the first extender receiver to receive the first extender portion and the second extender receiver to receive the second extender portion to couple the fork terminal to the second fastening mechanism.
